(19) United States
(12) Patent Application Publication
(10) Pub. No.: US 2012/0312370 A1
(43) Pub. Date: Dec. 13, 2012

(54) HYBRID DYE-SENSITIZED SOLAR CELL PHOTOANODES BASED ON AQUEOUS SYNTHESIZED TITANIUM DIOXIDE

(75) Inventors: George P. DEMOPOULOS, Montreal (CA); Cecile CHARBONNEAU, Swansea (GB)

(73) Assignee: MCGILL UNIVERSITY, Montreal (CA)

(21) Appl. No.: 13/490,903

(22) Filed: Jun. 7, 2012

Related U.S. Application Data
(60) Provisional application No. 61/494,017, filed on Jun. 7, 2011.

(51) Int. Cl. H01B 1/20; H01B 1/08; H01L 31/0224

(52) U.S. Cl. 136/256; 252/500; 252/520.2; 252/519.32; 252/519.3

(57) ABSTRACT

The invention describes a novel process for the aqueous synthesis of rutile and anatase nanocrystallites, their blending for preparation of a hybrid paste for single-layer (bi-functional) film deposition and the formulation of new water-based TiO₂ screen printing paste for the fabrication of dye-sensitized solar cells (DSSC) photoanodes.

### FIELD OF THE INVENTION

The invention relates generally to dye-sensitized solar cells (DSSC), comprising the use of a blend of aqueous-synthesized titanium dioxide nanopowders of different crystal structure formulated into pastes to form photoanodes for DSSCs.

### BACKGROUND OF THE INVENTION

With a growing demand for energy combined with the prospect of global warming and climate change, research and development efforts for the development of renewable energy sources such as solar have intensified. Considering the abundance of solar radiation reaching the Earth (some 120,000 TW compared to a current global consumption of ˜15 TW), solar energy constitutes a strategic energy source if cost-effective solar cell technologies are widely developed and implemented. Photovoltaic (PV) cell production capacity increased 87% in 2008 over 2007 reaching a total production capacity of 7 GWp-a, 6-fold increase since 2004. However, the production of PV modules is still based mainly on ultra pure silicon (>90%) that is very expensive. New generation solar cell technologies based on thin films and nanostructures are currently researched as potential breakthrough technologies that can render solar energy widely accessible at low cost. For that to happen, both semiconductor material design and cell processing/fabrication issues have to be successfully addressed.

The dye-sensitized solar cell (DSSC) has become one of the most promising solar cells in the renewable energy research and development field due to its good efficiency and potentially low fabrication cost. The DSSC consists of a working electrode, counter electrode and electrolyte. The conventional working electrode, that is, the photoanode, is made of a double-layer structure (FIG. 1) comprising a transparent layer of titanium dioxide (TiO₂) anatase nanoparticles (typically 10-30 nm) on which dye molecules, that is, the sensitizers, are adsorbed plus a light-scattering layer of TiO₂ rutile nanoparticles (typically 150 nm-500 nm). Upon sunlight absorption, the dye is promoted into an electronically excited state (1) from where it injects an electron into the conduction band of the TiO₂ layer (2), which in turn moves by diffusion to the external circuit (3), as illustrated in FIG. 2. Meanwhile, the dye molecule is returned to its ground state by accepting an electron from iodide in the electrolyte which is oxidized into triiodide (4). The triiodide then diffuses to the counter electrode of the cell, where it obtains electrons arriving through the external circuit and is reduced back to iodide (5).

The properties of the TiO₂ material used, namely the particle size and morphology [2-4], crystallinity, and phase content, have been extensively studied and shown to have a significant bearing on the overall efficiency of DSSC devices. The average particle size and particle size distribution need to be balanced so that the semiconductor film is characterized with a high surface area (to maximize the dye loading) and an average porosity in the mesoporous range (2-50 nm average pore size), to allow the diffusion of the dye and the electrolyte within the film. With respect to this issue, Miranda et al. [1] reported that the overall performance of DSSC devices was optimized with photoanodes fabricated from powders with bimodal crystal size distribution consisting of two classes of nanocrystals, 5 and 50-100 nm in size, as compared to photoanodes based on powders with unimodal crystal size distribution. Crystalline anatase nanoparticles are preferred for DSSC applications due to their larger bandgap than that of rutile nanoparticles. However, Li et al. [2] recently found that the introduction of 10-15% rutile nanoparticles significantly improved light harvesting and the overall solar conversion efficiency.

The TiO₂ material is incorporated into the formulation of a paste that can be uniformly deposited on conductive transparent substrates by using the screen-printing technique. The paste formulation is known to greatly affect the mechanical and adhesion properties of TiO₂ films. Typically, the screen-printing paste is prepared by mixing TiO₂ nanopowders with a binder, such as ethyl cellulose or polyethylene glycol and a rheological agent, typically a-terpineol or Triton X. The obtained mixture is further condensed by evaporation until an appropriate viscosity and TiO₂ content has been reached. Each component of the paste has a specific functionality. The binder is used to create the voids in between the particles and the rheological agent controls the dispersion of the particles and the viscosity of the paste.

Finally, the structure of the photoanode also plays an important role in the performance of DSSCs. The addition of a scattering overlayer containing TiO₂ particles with larger diameter (150-500 nm), on top of the transparent layer (made of nanocrystalline anatase particles, nc-TiO₂), was found to enhance the photocurrent and resulting performance of DSSCs by up to 15%. The function of the scattering layer is to scatter back the incident photons that were not absorbed by the dye while traveling across the transparent layer, this way enhancing the light collection properties of the photoanode. Each layer deposition is followed by annealing, involving a specific heating ramp. The double-layer structure of the film of prior art is shown in FIG. 1. The scattering effect may also be achieved by adding an overlayer containing submicron size cavities acting as scattering centres, for instance characterized with an inverse opal structure, such as suggested by Tao et al. [10] or specially designed beads [4]. However, multi-layer deposition or specially designed bead particle structures add complexity in the manufacturing process rendering it prohibitively expensive. For example, the whole process, sol-gel/hydrothermal synthesis of nc-anatase, paste making, double-layer film deposition and annealing takes 8 days.

There is a need to avoid the use of organic solvents, shorten the manufacturing time, lower the costs to manufacture photoanodes for DSSCs, and have DSSCs that exhibit increased overall photoelectric efficiency.

### SUMMARY OF THE INVENTION

In one aspect of this invention, there is provided a paste formulation comprising a blend of aqueous-synthesized titanium dioxide anatase nanocrystallites and aqueous-synthesized titanium dioxide rutile nanostructured particles.

In accordance with one aspect of the present invention, there is provided a paste for forming a titanium dioxide porous layer comprising a solids blend comprising an aqueous-synthesized anatase nanocrystallites and an aqueous-synthesized rutile nanostructured particles, and a solvent.

In accordance with one aspect of the paste herein described, the solvent comprises alpha-terpineol, ethyl-cellulose, ethanol, water and acetic acid.

In accordance with another aspect, the paste herein described comprises 5 to 20% of the solids blend by weight of the paste 40 to 50% alpha-terpineol by weight of the paste; 5 to 10% ethyl-cellulose by weight of the paste; 30 to 35% ethanol by weight of the paste; 0.1 to 0.5% water by weight of the paste; and 0.1 to 0.5% acetic acid by weight of the paste.

In accordance with yet another aspect, the paste herein described comprises about 45% alpha-terpineol by weight of the paste; about 7.5% ethyl-cellulose by weight of the paste; about 32.5% ethanol by weight of the paste; about 0.3% water by weight of the paste; and about 0.3% acetic acid by weight of the paste.

In accordance with still another aspect of the paste herein described, the solvent comprises water, acetic acid, polyethylene glycol and propylene glycol.

In accordance with yet still another aspect, the paste herein described comprises 5 to 20% of the solids blend by weight of the paste; 50 to 55% water by weight of the paste; 0.1 to 1.0% acetic acid by weight of the paste; 5 to 10% polyethylene glycol by weight of the paste; and 25 to 35% propylene glycol by weight of the paste.

In accordance with a further aspect, the paste herein described comprises about 52.5% by weight of water, about 0.6% by weight of acetic acid, about 7.5% by weight of polyethylene glycol, and about 30% by weight of propylene glycol.

In accordance with yet a further aspect of the paste herein described, the anatase nanocrystallites have a particle diameter less than 50 nm, and the rutile particles have a particle diameter less than 1000 nm.

In accordance with still a further aspect of the paste herein described, the anatase nanocrystallites have a particle diameter in a range from 4 to 10 nm, and the rutile particles have a range from 100 to 500 nm.

In accordance with yet still a further aspect of the paste herein described, the anatase nanocrystallites and the rutile particles are at a weight ratio of 10/90 to 90/10 within the solids blend.

In accordance with one embodiment of the paste herein described, the solids blend further comprises up to 30% of commercially available TiO₂ nano or sub-micron particles by weight of the solids blend.

In accordance with another embodiment of a photoanode for a dye-sensitized solar cell with at least one porous titanium dioxide layer that carries a sensitizing dye wherein the titanium dioxide porous layer is made from the paste herein described.

In accordance with yet another embodiment of a dye-sensitized solar cell that includes the photoanode herein described, and a cathode on the opposite side of the photoanode holding an electrolyte layer in between the photoanode and cathode.

From another aspect, a photoanode for a dye-sensitized solar cell with at least one porous titanium dioxide layer that carries a sensitizing dye wherein the titanium dioxide porous layer is made from the paste formulation containing a blend of aqueous-synthesized titanium dioxide anatase nanocrystallites and aqueous-synthesized titanium dioxide rutile nanostructured particles and further containing 52.5% by weight of water, 0.6% by weight of acetic acid, 7.5% by weight of polyethylene glycol and 30% by weight of propylene glycol.

In accordance with another embodiment there is provided a dye-sensitized solar cell that includes a photoanode with at least one porous titanium dioxide layer that carries a sensitizing dye wherein the titanium dioxide porous layer is made from the paste formulation containing a blend of aqueous-synthesized titanium dioxide anatase nanocrystallites and aqueous-synthesized titanium dioxide rutile nanostructured particles and further containing 45% by weight of alpha-terpineol, 7.5% by weight of ethyl-cellulose, and 32.5% by weight of ethanol, and 0.3% by weight of water and 0.3% by weight of acetic acid, and a cathode on the opposite side of the photoanode holding an electrolyte layer in between the photoanode and cathode.

In accordance with another embodiment there is provided a dye-sensitized solar cell that includes a photoanode with at least one porous titanium dioxide layer that carries a sensitizing dye wherein the titanium dioxide porous layer is made from the paste formulation containing a blend of aqueous-synthesized titanium dioxide anatase nanocrystallites and aqueous-synthesized titanium dioxide rutile nanostructured particles and further 52.5% by weight of water, 0.6% by weight of acetic acid, 7.5% by weight of polyethylene glycol and 30% by weight of propylene glycol, and a cathode on the opposite side of the photoanode holding an electrolyte layer in between the photoanode and cathode.

### BRIEF DESCRIPTION OF THE DRAWINGS

Further aspects and advantages of the present invention will become better understood with reference to the description in association with the following drawings in which:

FIG. 1 is a schematic representation of a double layer photoanode dye-sensitized solar cell (PRIOR ART);

FIG. 2 is a diagram representing the working principle of a DSSC (Dye-Sensitized Solar Cell;

FIG. 3a is a flow chart corresponding to the aqueous synthesis of anatase and rutile nc-TiO₂ materials that can be recovered as wet gels or dry powders;

FIG. 3b is a flow chart corresponding to a formulation of a water-based TiO₂ paste developed for screen-printing of photoanodes, with the experimental steps successively described;

FIG. 4 illustrates a schematic view of the hybrid photoanode-based dye-sensitized solar cell, according to the present invention where the photoanode contains both a large surface area nc-anatase and light-scattering nc-rutile material within a single layer;

FIG. 5 illustrates a comparison between the different steps involved in the procedure for the fabrication of single-layer hybrid and double-layer photoanodes and illustrating the process simplification resulting from a single as opposed to a double layer deposition;

FIG. 6a illustrates the first step of deposition of a single layer of TiO₂ at laboratory scale according to one embodiment of the invention showing the uniform application of the paste using a spatula;

FIG. 6b illustrates the use of adhesive tape on top of the single layer;

FIG. 6c illustrates the use of a sharp blade to delimit the final square shape of the photoanode; and

FIG. 6d shows the deposited film before being sent to annealing/sintering;

FIG. 7 illustrates the successive heating steps and temperature ramps involved in the annealing cycle;

FIG. 8 illustrates the comparison of photovoltaic measurements of DSSC devices based on single layer photoanodes made from 100% aqueous-synthesized anatase, hybrid aqueous-synthesized 50/50 nc-anatase/rutile powders (conventional paste formulation), and double layer aqueous-synthesized nc-anatase (conventional paste formulation) topped with a scattering layer (WER4-O reflector paste from Dyesol);

FIG. 9 illustrates the comparison of photovoltaic measurements of DSSC devices based on single layer photoanodes (6-7 μm thickness) made from water-based (novel paste formulation) hybrid paste containing 100%, 90%/10%, 80%/20%, 20%/80% aqueous-synthesized nc-rutile/anatase, and commercial paste 18-NR-T from Dyesol.

### DETAILED DESCRIPTION OF THE INVENTION

The aspects of the present invention will be described more fully hereinafter with reference to the accompanying drawings. This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including”, “comprising”, or “having”, “containing”, “involving” and variations there of herein, is meant to encompass the items listed thereafter as well as, optionally, additional items.

The term “hybrid” as used herein, can also refer to composite or nanocomposite or blend(s). The term “paste” as used herein can also refer to dispersion or slurry.

A novel photoanode as part of a dye sensitized solar cell (DSSC) is designed and fabricated in this invention by application of a new composite screen-printable titanium dioxide paste. The photoanode of this invention is illustrated in FIG. 4. The photoanode comprises at least a one layer structure made up of a dye-adsorbed composite titanium dioxide layer on conductive glass or other substrate; wherein the cost to produce the titanium dioxide paste and the photoanode is low and the conversion efficiency of the DSSC using the novel photoanode is enhanced or equivalent to a double-layer structure photoanode.

The composite paste is made using known organic-solvent based formulations or using water-based formulations, and from anatase and rutile varieties of titanium dioxide nanoparticles produced by aqueous-synthesis.

1) Synthesis of Titanium Dioxide Particles

The synthesis of the nanocrystalline (nc)-anatase typically 0.2M and rutile (scattering) typically 0.3-5M particle varieties involves spontaneous homogeneous nucleation by forced hydrolysis of variable concentration TiCl₄ aqueous solutions at 80° C. (30 minutes to 2 hour processing) at atmospheric pressure. The crystallite size of the aqueous-synthesized nc-anatase material is typically 4-10 nm, in comparison to the commercially available materials that are 20-30 nm. TGA (thermo gravimetric) analysis revealed the presence of ˜1-3 wt. % chemically bound hydroxyl content in the annealed nc-anatase transparent film. The presence of Ti—OH surface groups was substantiated by spectroscopic analysis. Apparent improved anchoring of the dye via the OH-populated anatase nanocrystallites was observed that implies that a paste made from aqueous-synthesized titanium dioxide can lead to higher conversion efficiency as indeed was measured in a comparative study involving cells built with commercial and the in-house made product [5,6]. The aqueous synthesis process may be modified (operated with >0.2 M TiCl₄ solutions) to favour the production of rutile nanostructured particles. The rutile particles (80-120 m²/g and 100-500 nm size) so synthesized have a unique self-assembled nanofibre structure (“urchin” variety) [17] that makes them highly desirable for the scattering layer or the scattering function.

The fabrication of nanocrystalline-TiO₂ materials via aqueous synthesis as opposed to sol-gel/hydrothermal or solvothermal processes reduces at the same time the costs in terms of energy consumption and processing time (30 min-2 hr at 80° C. for the aqueous-synthesis vs. typically 0.5-3 days of processing at 150-250° C. for the sol-gel/hydrothermal or solvothermal methods). Moreover, the aqueous-synthesis method is much less chemical intensive than sol-gel/solvothermal processes such as designed to synthesize titanium dioxide beads. The use of a simple chemical reactor operated under atmospheric pressure is another advantage when compared to the use of pressure autoclaves required for the crystallization of TiO₂ products issued from sol-gel synthesis.

2) Composite Titanium Dioxide Material-Conventional Paste Formulation

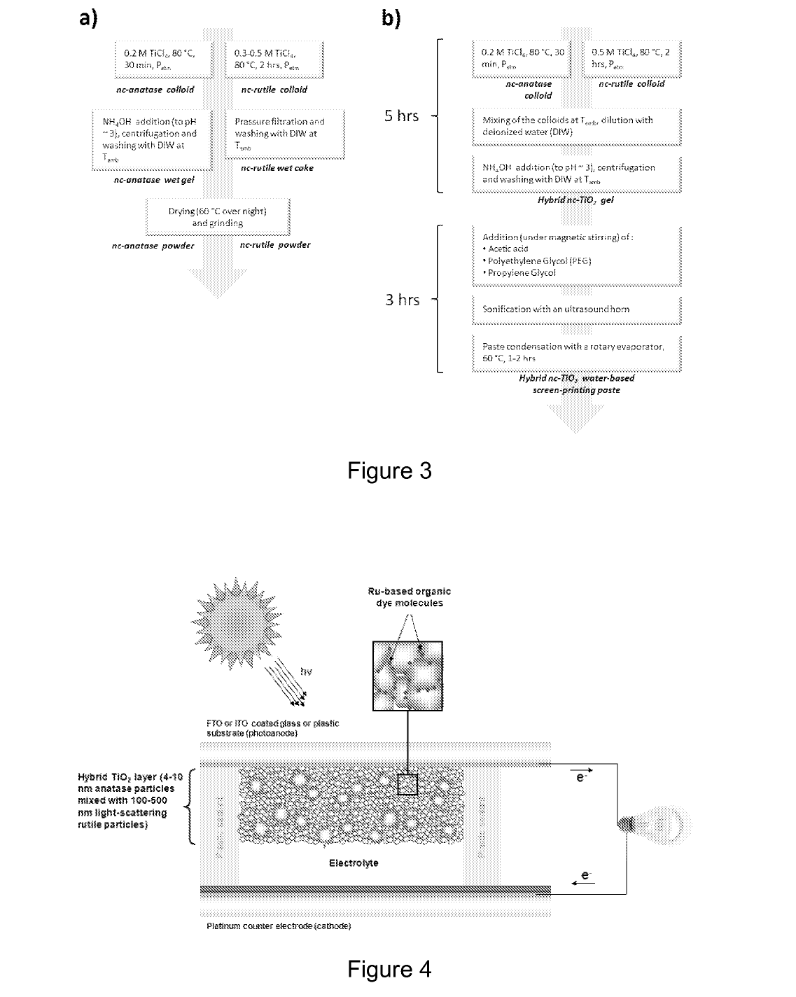

The so-produced by aqueous synthesis nc-anatase and rutile particles may be blended at various ratios to prepare hybrid (composite) paste using the standard (conventional) formulation reported by Grätzel's group which is based on organic solvents. Preparation of such hybrid paste can lead to simplification of the whole paste manufacturing/photoanode film fabrication process via single-layer (instead of “double-layer”) film deposition (FIGS. 6 & 7). The composite paste is made from anatase nanocrystallites [9] and nanofiber-structured rutile particles [7]. The respective TiO₂ varieties may be separated from their synthesis liquor as follows: in the case of the anatase nanocrystallites upon their formation the synthesis liquor is neutralized, for example with NH₄OH, to a pH higher than 1 but preferably 3 and then subjected to centrifugation and washing with deionized water at ambient temperature; in the case of the rutile material, separation can be effected by pressure filtration and washing (FIG. 3.a). The so-collected gels are further dried (preferably at 60° C. overnight) and ground prior to paste preparation. For the paste, as per Grätzel's recipe, ethanol is used as a solvent, alpha-terpineol as a rheological agent and ethyl-cellulose as a spacer [8]. The resulting film (deposited on FTO-coated glass, Fluorine-doped Tin Oxide) had ˜5 μm thickness. A series of cells was fabricated and compared in terms of efficiency. Surprisingly, the single-layer cell based on the composite paste (50/50 nc-anatase/rutile) yielded 4.07% efficiency (Table I). By comparison a double-layer (transparent nc-TiO₂ plus scattering layer)-based DSSC (with equivalent thickness transparent film ˜5 μm) yielded 3.46% efficiency.

The hybrid (composite) paste prepared with various fractions of aqueous synthesized anatase (A) and rutile (R) can be advantageously further blended with other intermediate size TiO₂ particles to those of A and R so to provide after screen printing and sintering photoanodes with optimized porosity hence better electrode/electrolyte interface, an important consideration for improving the conversion efficiency of the device. Thus as it can be seen with the data of Table II the efficiency of a device made with 60% R/40% A saw its efficiency improved from 4.54% to 5.41% when part of the anatase material (4-10 nm size) was replaced with a commercially available P25 TiO₂ particles of ˜30 nm in size. The efficiency was further improved to ˜7% this time when the 40% A content was restored by reducing the rutile content to 40% and still using 20% P25. This is impressive as the amount of aqueous anatase was only 40% or combined with P25 the total anatase amount was only 60% of a 5-6 μm thick film. Apparently the incorporation of a small amount of P25 TiO₂ contributes not only to better connectivity between aqueous anatase and rutile but also enhanced porosity. More importantly, the average thickness of hybrid electrodes is only 5˜6 μm, which is half of that of conventional cells (12˜15 μm). By comparison electrodes built with the Dyesol benchmark paste and having similar thickness yielded lower performance (4.94%) this increasing to 6.74% at double thickness. It is postulated that the unique characteristics of the aqueous-synthesized anatase crystallites (in terms of surface area and hydroxylation) [18] allowing for improved dye coating [19] in combination with the effective scattering properties of the “sea-urchin” rutile particles greatly enhance light harvesting and electron injection/collection hence the observed high performance despite the thinner film.

3) Water-Based Composite Paste Formulation

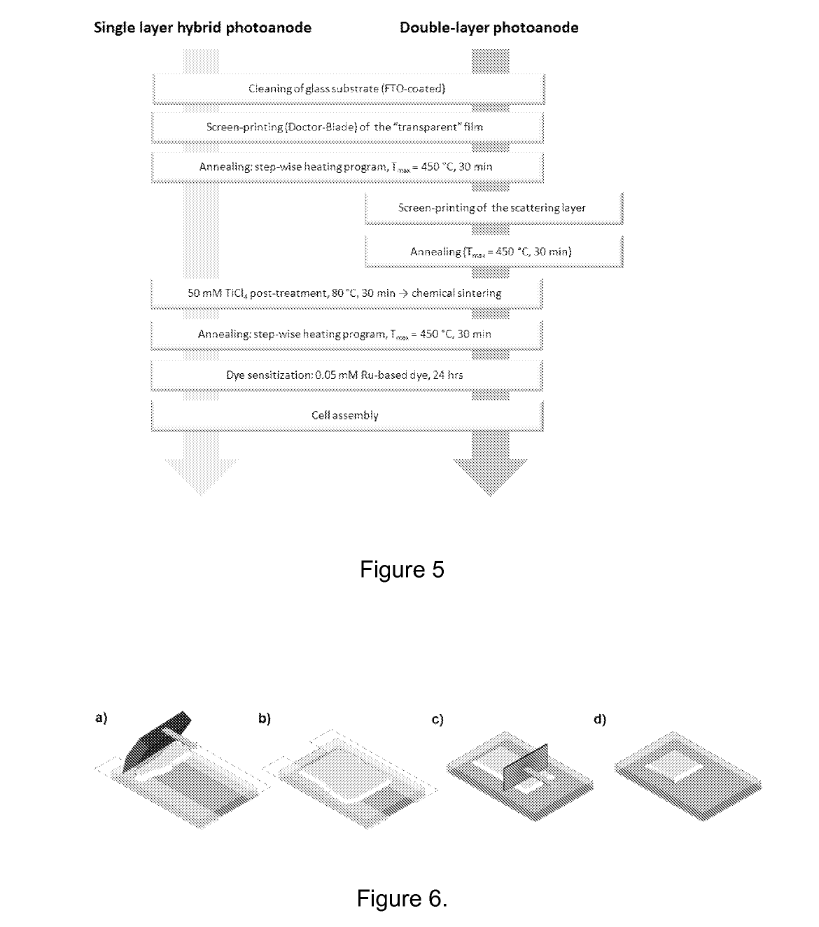

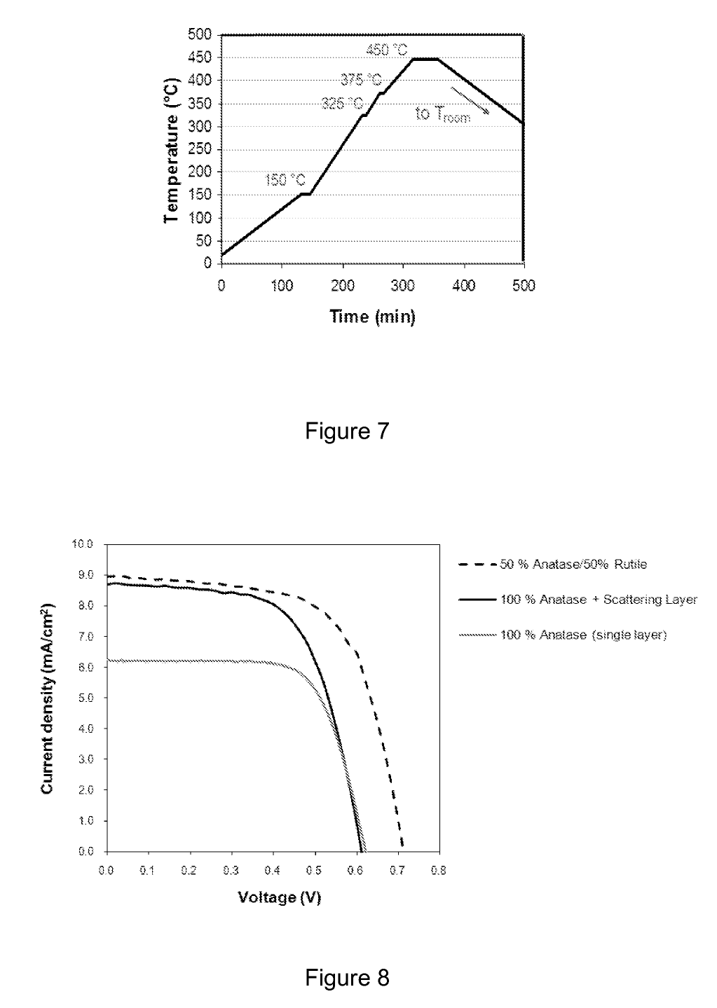

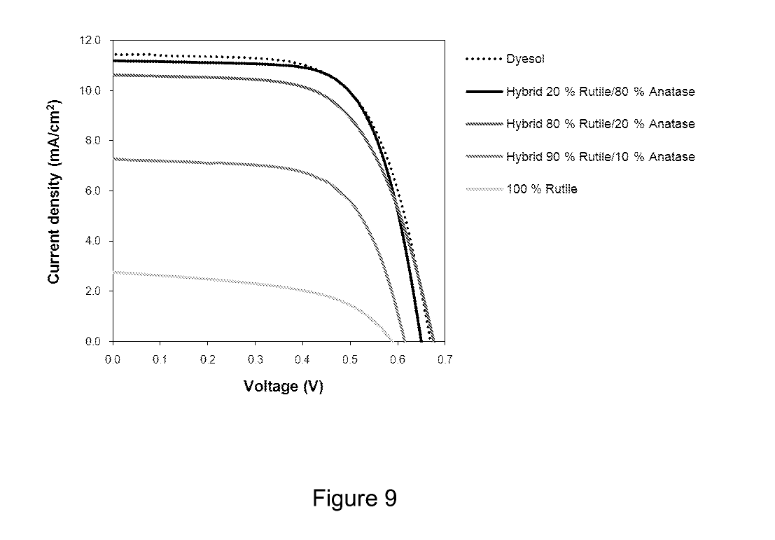

Another paste formulation has now been advanced that allows for seamless integration of the aqueous synthesis and paste preparation stages. The new paste formulation is 100% water-based not using toxic organic solvents such as a-terpineol. Preparation of the paste is made according to several steps described in FIG. 3.b. First, the nanocrystallite anatase is prepared starting with 0.2M TiCl₄ heated to 80° C. for at least 30 minutes. The nanocrystalline rutile colloid begins with 0.5M TiCl₄ heated at 80° C. for at least two hours at atmospheric pressure. The colloids are mixed at ambient temperature with deionized water. The mixed TiO₂ material (e.g. nc-TiO₂ nanoparticles) is recovered under the form of a hybrid-aqueous gel (10-15 wt. % solid) by neutralization, for example with ammonium hydroxide (NH₄OH) up to pH 3 (a pH that favours reversible aggregation and fast settling of the nanoparticles), and centrifugation. Solid-liquid separation follows to remove the major part of the chloride-containing synthesis liquor. Second, acetic acid (200 μL per gram of TiO₂) and a small amount of water are added to the TiO₂ aqueous gel under stirring to ensure a good dispersion of the particles and homogeneity of the liquid gel. Third, the binder, polyethylene glycol (PEG 20,000, previously dissolved in water, 10 wt. %), and the rheological agent, propylene glycol, are added to the gel (0.5 g of PEG 20,000 and 2 g of propylene glycol per gram of TiO₂). Ultrasound (sonification) is applied with an ultrasonic horn to the final mixture in order to ensure high homogeneity. Finally, this mixture is condensed in a rotary evaporator at 50° C. until the solid content reaches 15-20 wt. %. This new paste formulation was applied to the hybrid (nc-anatase/rutile) material obtained by aqueous synthesis for the fabrication of single-layer photoanodes. Fabrication of the hybrid photoanode (FIG. 5) was done by uniformly spreading the paste on the conductive side of a glass substrate (FIG. 6), further submitted to annealing by step-wise heating (up to 450° C., 30 min, FIG. 7). The results are summarized in Table III. Surprisingly, a single-layer DSSC built with the above water-based paste formulation yielded equivalent results as the hybrid material with the conventional (ethyl cellulose and a-terpineol-based) formulation. Thus a 4.45% average efficiency was obtained using the novel aqueous-based paste and aqueous synthesized TiO₂ (20 wt. % “sea urchin” 200 nm rutile and 80% 5 nm anatase), which is higher than the performance of 4.37% conversion efficiency obtained for a cell which photoanode was fabricated using the commercial paste 18NR-T from Dyesol. The photoanodes were 6-7 μm thick.

The formulation of water-based TiO₂ screen printing pastes offers considerable advantages in terms of cost, operations, and environment compatibility, when compared to the conventional organic-based paste recipe. Direct incorporation of a customizable hybrid aqueous-synthesized nc-TiO₂ gel to the paste recipe allows for great process simplification and energy saving by avoiding drying and grinding of nc-TiO₂ materials. The recipe developed for the preparation of a water-based paste as opposed to the conventional organic-based paste uses by far less toxic and already widely used chemicals such as glycol derivatives (as opposed to a-terpineol and ethyl-cellulose, the main components of the conventional ethanolic paste).

4) New Photoanode Made from Composite Paste

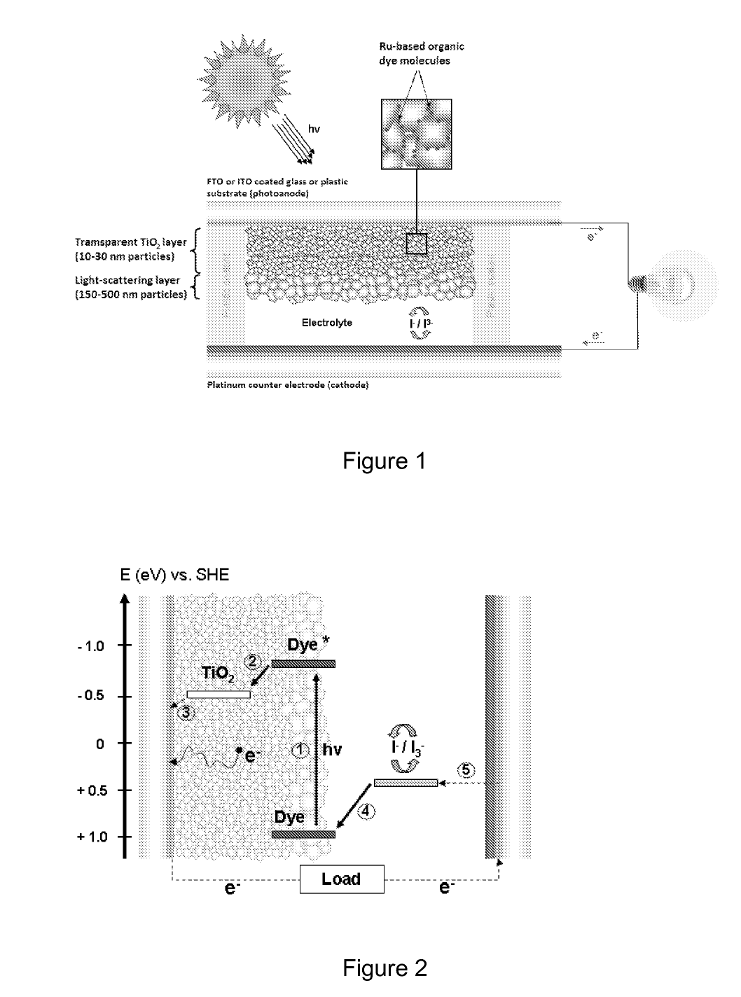

The deposition of a single bi-functional layer, encompassing both large surface area and light-scattering properties necessary for optimized dye loading and photon collection, reduces the energy costs and processing time associated to photoanode preparation by avoiding the deposition and annealing of a light-scattering overlayer on top of the transparent thin film (FIGS. 1 & 5).

The new pastes and photoanodes constitute low-cost, simplified and green alternatives to the methods (sol-gel/hydrothermal) and products (separate pastes for “double-layer” film deposition) currently available for the fabrication of DSSC photoanodes.

Exemplary embodiments of present invention are provided in the following examples. These examples are presented by way of illustration and are not intended in any way to otherwise limit the scope of the invention.

### Example 1

The titanium dioxide particles were synthesized by forced hydrolysis at variable concentrations of TiCl₄ aqueous solutions. The anatase nanocrystallite TiO₂ was made at 80° C. using 0.2 M TiCl₄ aqueous solution treated for 30 minutes. The rutile TiO₂ particles were made at 80° C. using 0.3 M TiCl₄ aqueous solution treated for 2 hours. The individual TiO₂ powders (anatase and rutile) were separated by filtration, washed and dried in an oven before used to make paste with the conventional recipe.

TABLE 1
Characteristics and performance of the DSSC devices fabricated with
single layer photoanodes made from 100% aqueous-synthesized anatase,
hybrid aqueous-synthesized 50/50 nc-anatase/rutile powders (conventional
paste formulation), and double layer aqueous-synthesized nc-anatase
(conventional paste formulation) topped with a scattering layer
WER4-O reflector paste from Dyesol).

| | Isc | Voc | FF | ηₘₐₓ | Thickness |
|---|---|---|---|---|---|
| | (mA/cm²) | (V) | (%) | (%) | (μm) |
| 100% A | 6.25 | 0.620 | 70 | 2.70 | 12.9 |
| 100% A + Scatt. layer | 8.71 | 0.610 | 65 | 3.46 | 4.7¹ |
| 50% A/50% R | 8.96 | 0.710 | 64 | 4.07 | 8.0 |

¹Thickness of nc-TiO₂ layer only (A)

### Example 2

The titanium dioxide particles were synthesized by forced hydrolysis at variable concentrations of TiCl₄ aqueous solutions. The anatase nanocrystallite TiO₂ was made at 80° C. using 0.2 M TiCl₄ aqueous solution treated for 30 minutes. The rutile TiO₂ particles were made at 80° C. using 0.5 M TiCl₄ aqueous solution treated for 2 hours. The individual TiO₂ powders (anatase and rutile) were separated by filtration, washed and dried in an oven before used to make paste with the conventional recipe [12]. In this case, however in addition to the so prepared aqueous synthesized anatase (A) and rutile R) particles, commercial P25 particles were added also at various fractions in making the paste.

TABLE II
Characteristics and performance of the DSSC devices fabricated
with single layer photoanodes (5-6 μm thickness) made from
(conventional formulation) hybrid paste containing P25 particles
along various fractions of aqueous-synthesized rutile/anatase.
As reference the performance of devices made with the commercial
paste 18NR-T from Dyesol was measured and included.

| | J_{SC} | V_{oc} | FF | ηₚₑₐₖ | η_{average} | Thickness |
|---|---|---|---|---|---|---|
| | (mA/cm²) | (V) | (%) | (%) | (%) | (μm) |
| 60% R/40% A | 11.10 | 0.62 | 67 | 4.54 | 4.14 | 5-6 |
| 60% R/20% A/ | 11.27 | 0.72 | 66 | 5.41 | 4.57 | |
| 20% P25 | | | | | | |
| 40% R/40% A/ | 14.85 | 0.74 | 64 | 7.04 | 6.92 | |
| 20% P25 | | | | | | |
| Dyesol (NR18-T) | 11.48 | 0.67 | 65 | 4.94 | 4.37 | |
| Dyesol (NR18-T) | 15.99 | 0.65 | 0.65 | 6.74 | 6.35 | 10-11 |

### Example 3

The titanium dioxide particles were synthesized by forced hydrolysis at variable concentrations of TiCl₄ aqueous solutions. The anatase nanocrystallite TiO₂ was made at 80° C. using 0.2 M TiCl₄ aqueous solution treated for 30 minutes. The rutile TiO₂ particles were made at 80° C. using 0.5 M TiCl₄ aqueous solution treated for 2 hours. The individual TiO₂ powders (anatase and rutile) were collected as wet cake/gels and used directly to make the paste (novel paste formulation as described in [0039]) without prior drying.

TABLE III
Characteristics and performance of the DSSC devices fabricated
with single layer photoanodes (6-7 μm thickness) made from
water-based (novel paste formulation) hybrid paste containing
100%, 90%/10%, 80%/20%, 20%/80% aqueous-synthesized
rutile/anatase, and commercial paste 18-NR-T from Dyesol.

| | Isc | Voc | FF | ηₘₐₓ | η_{average} | Thickness |
|---|---|---|---|---|---|---|
| | (mA/cm²) | (V) | (%) | (%) | (%) | (μm) |
| 100% R | 2.76 | 0.59 | 51 | 0.82 | 0.50 | 6.3 |
| 90% R/10% A | 7.30 | 0.61 | 64 | 2.89 | 2.83 | 6.6 |
| 80% R/20% A | 10.64 | 0.68 | 62 | 4.47 | 3.73 | 6.0 |
| 20% R/80% A | 11.20 | 0.65 | 67 | 4.94 | 4.45 | 7.4 |
| Dyesol (NR18-T) | 11.48 | 0.67 | 65 | 4.94 | 4.37 | 6.4 |

### REFERENCES

[1] L. Miranda, A. Chianese, Chem. Eng. Trans., 17 (2009), 975.
[2] G. Li, C. P. Richter, R. L. Milot, L. Cai, C. A. Schmuttenmaer, R. H. Crabtree, G. W. Brudvig, V. S. Batista, Dalton Trans., 45 (2009), 10078.
[3] C.-A. Tao, W. Zhu, Q. An, G. Li, J. Phys. Chem. C, 114 (2010), 10641.
[4] F. Huang, D. Chen, X. L. Zhang, R. A. Caruso, Y.-B. Cheng, Adv. Funct. Mater., 20 (2010), 1301.
[5] G. P. Demopoulos, C. Charbonneau, K. E. Lee, G. B. Shan, M. A. Gomez, and R. Gauvin, ECS Transactions, 21 (2009), 23.
[6] C. Charbonneau, K. E. Lee, G. B. Shan, M. A. Gomez, R. Gauvin, and G. P. Demopoulos, Electrochem. Sol. State Lett., 13 (8) (2010), H257.
[7] C. Charbonneau, R. Gauvin and G. P. Demopoulos, J. Cryst. Growth, 312 (2009), 86.
[8] S. Ito, P. Chen, P. Comte, M. K. Nazeeruddin, P. Liska, P. Péchy, and M. Grätzel, Prog. Photovolt.: Res. Appl., 15 (2007), 603.
[9] C. Charbonneau, R. Gauvin and G. P. Demopoulos, J. Electrochem. Soc., 158 (2011), H224.
[10] S. Ito, T. N. Murakami, P. Comte, P. Liska, C. Grätzel, M. K. Nazeeruddin, M. Grätzel, Thin Sol. Films, 516 (2008), 4613.
[11] C.-Y. Huang, Y.-C. Hsu, J.-G. Chen, V. Suryanarayanan, K.-M. Lee, K.-Ch. Ho, Sol. Energy Mater. Sol. Cells, 90 (2006), 2391.
[12] C. Baek, M. Vithal, J. A. Chang, J. H. Yum, M. K. Nazeeruddin, M. Grätzel, Y. C. Chung, S. Seok, Electrochem. Commun., 11 (2009), 909.
[13] Y. Lei, H. Liu, W. Xiao, Modelling Simul. Mater. Sci. Eng., 18 (2010), 025004.
[14] N.-G. Park, J. van de Lagemaat, A. J. Frank, J. Phys. Chem. B, 104 (2000), 8989.
[15] K. Fan, M. Liu, T. Peng, L. Ma, K. Dai, Renewable Energy, 35 (2010), 555.
[16] H.-J. Koo, J. Park, B. Yoo, K. Yoo, K. Kim, N.-G. Park, Inorg. Chim. Acta, 361 (2008), 677.
[17 K. E. Lee, M. A. Gomez, C. Charbonneau and George P. Demopoulos: Enhanced surface hydroxylation of nanocrystalline anatase films improves photocurrent output and electron lifetime in dye sensitized solar cell photoanodes. Electrochim. Acta. 67, 208-215 (2012).

1. A paste for forming a titanium dioxide porous layer comprising
a solids blend comprising
an aqueous-synthesized anatase nanocrystallites and
an aqueous-synthesized rutile nanostructured particles, and
a solvent.

2. The paste according to claim 1, wherein the solvent comprises alpha-terpineol, ethyl-cellulose, ethanol, water and acetic acid.

3. The paste according to claim 2, comprising
5 to 20% of the solids blend by weight of the paste
40 to 50% alpha-terpineol by weight of the paste;
5 to 10% ethyl-cellulose by weight of the paste;
30 to 35% ethanol by weight of the paste;
0.1 to 0.5% water by weight of the paste; and
0.1 to 0.5% acetic acid by weight of the paste.

4. The paste according to claim 3, comprising
about 45% alpha-terpineol by weight of the paste;
about 7.5% ethyl-cellulose by weight of the paste;
about 32.5% ethanol by weight of the paste;
about 0.3% water by weight of the paste; and
about 0.3% acetic acid by weight of the paste.

5. The paste according to claim 1, wherein the anatase nanocrystallites have a particle diameter less than 50 nm, and the rutile particles have a particle diameter less than 1000 nm.

6. The paste according to claim 5, wherein the anatase nanocrystallites have a particle diameter in a range from 4 to 10 nm, and the rutile particles have a range from 100 to 500 nm.

7. The paste according to claim 6, wherein the anatase nanocrystallites and the rutile particles are at a weight ratio of 10/90 to 90/10 within the solids blend.

8. The paste according to claim 7, wherein the solids blend further comprises up to 30% of commercially available TiO₂ nano or sub-micron particles by weight of the solids blend.

9. A photoanode for a dye-sensitized solar cell with at least one porous titanium dioxide layer that carries a sensitizing dye wherein the titanium dioxide porous layer is made from the paste according to claim 3.

10. The paste according to claim 1, wherein the solvent comprises water, acetic acid, polyethylene glycol and propylene glycol.

11. The paste according to claim 10, comprising
5 to 20% of the solids blend by weight of the paste;
50 to 55% water by weight of the paste;
0.1 to 1.0% acetic acid by weight of the paste;
5 to 10% polyethylene glycol by weight of the paste; and
25 to 35% propylene glycol by weight of the paste.

12. The paste according to claim 11, comprising
about 52.5% by weight of water,
about 0.6% by weight of acetic acid,
about 7.5% by weight of polyethylene glycol, and
about 30% by weight of propylene glycol.

13. The paste according to claim 12, wherein the anatase nanocrystallites have a particle diameter less than 50 nm, and the rutile particles have a particle diameter less than 1000 nm.

14. The paste according to claim 13, wherein the anatase nanocrystallites have a particle diameter in a range from 4 to 10 nm, and the rutile particles have a range from 100 to 500 nm.

15. The paste according to claim 14, wherein the anatase nanocrystallites and the rutile particles are at a weight ratio of 10/90 to 90/10 within the solids blend.

16. The paste according to claim 15, wherein the solids blend further comprises up to 30% of commercially available TiO₂ nano or sub-micron particles by weight of the solids blend.

17. A photoanode for a dye-sensitized solar cell with at least one porous titanium dioxide layer that carries a sensitizing dye wherein the titanium dioxide porous layer is made from the paste according to claim 11.

18. A photoanode for a dye-sensitized solar cell with at least one porous titanium dioxide layer that carries a sensitizing dye wherein the titanium dioxide porous layer is made from the paste according to claim 10.

19. A dye-sensitized solar cell that includes the photoanode of claim 9, and a cathode on the opposite side of the photoanode holding an electrolyte layer in between the photoanode and cathode.

20. A dye-sensitized solar cell that includes the photoanode of claim 18, and a cathode on the opposite side of the photoanode holding an electrolyte layer in between the photoanode and cathode.
